(19) United States
(12) Patent Application Publication
(10) Pub. No.: US 2009/0323276 A1
(43) Pub. Date: Dec. 31, 2009

(54) HIGH PERFORMANCE SPREADER FOR LID COOLING APPLICATIONS

(76) Inventors: Rajiv K. Mongia, Fremont, CA (US); Krishnakumar Varadarajan, Bangalore (IN); Anandaroop Bhattacharya, Bangalore (IN)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 12/491,097

(22) Filed: Jun. 24, 2009

(30) Foreign Application Priority Data
Jun. 25, 2008 (IN) 1519/DEL/2008

(51) Int. Cl. G06F 1/20; H05K 13/00

(52) U.S. Cl. 361/679.52; 29/592.1

(57) ABSTRACT

Apparatuses, systems, and methods for a heat spreader plate and pulsating heat pipes to transfer heat sourced from one or more electronic components are described herein. Other embodiments may also be described and claimed.

### CROSS-REFERENCE TO RELATED APPLICATION

The present application claims International Priority under 35 U.S.C. §119 to co-pending Indian Patent Application No. 1519/DEL/2008, filed Jun. 25, 2008, entitled “HEAT SPREADER PLATE WITH PULSATING HEAT PIPES”; the entire content and disclosure of which is hereby incorporated by reference in its entirety.

### FIELD

Embodiments of the present disclosure relate to thermal management and, in particular, to a heat spreader plate with pulsating heat pipes.

### BACKGROUND

Current thermal management arrangements may employ heat pipes to transport thermal energy from a heat source to a heat sink. The heat pipes are typically annular tubes with a fibrous wick material disposed therein. A liquid flow conveys a fluid along a center portion of the heat pipe from a condenser section to an evaporator section. At the evaporator section the liquid may evaporate through the fibrous wick material to a perimeter portion of the heat pipe. A vapor flow may then convey the fluid back to the condenser section, where the fluid will condense back through the fibrous wick material.

### BRIEF DESCRIPTION OF THE DRAWINGS

The present disclosure will be described by way of exemplary embodiments, but not limitations, illustrated in the accompanying drawings in which like references denote similar elements, and in which:

FIG. 1 is a schematic diagram of a system, in accordance with an embodiment;

FIGS. 2A and 2B are top and side cross-sectional views of a system, in accordance with an embodiment;

FIG. 3 is a schematic diagram of a system, in accordance with an embodiment;

FIG. 4 is a schematic diagram of a system, in accordance with an embodiment;

FIG. 5 is a laptop computing device, in accordance with an embodiment; and

FIG. 6 is a flow diagram illustrating a manufacturing operation of the thermal management arrangement, in accordance with an embodiment.

### DETAILED DESCRIPTION

In the following detailed description, numerous specific details are set forth in order to provide a thorough understanding of embodiments of the disclosure. However, those skilled in the art will understand that such embodiments may be practiced without these specific details. In other instances, well-known methods, procedures, and components have not been described in detail.

Although various discrete operations will be described herein, the mere order of description should not be construed as to imply that these operations are necessarily performed in the order they are presented.

The phrases “in some embodiments” and “in various embodiments” are used repeatedly. These phrases generally do not refer to the same embodiment; however, they may. The terms “comprising,” “having,” and “including” are synonymous, unless the context dictates otherwise.

The phrase “A and/or B” means (A), (B), or (A and B). The phrase “A/B” means (A), (B), or (A and B), similar to the phrase “A and/or B.” The phrase “at least one of A, B and C” means (A), (B), (C), (A and B), (A and C), (B and C) or (A, B and C). The phrase “(A) B” means (B) or (A B), that is, A is optional.

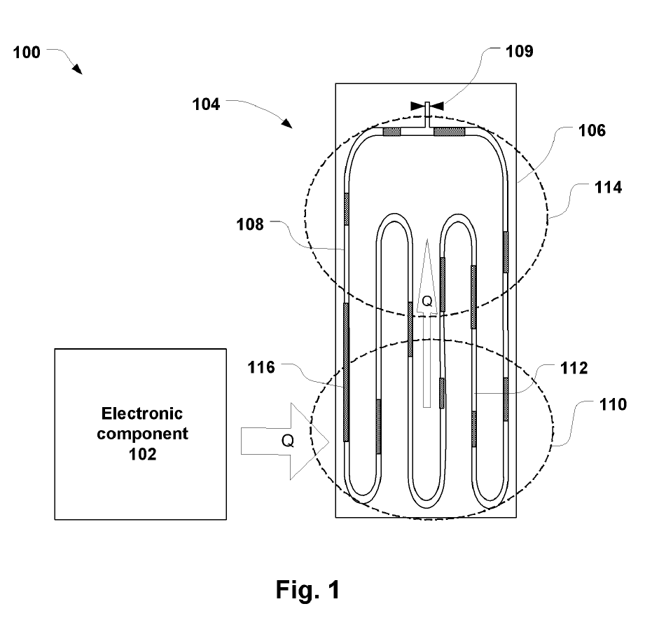

FIG. 1 is a schematic diagram of a system 100 in accordance with an embodiment. The system 100 may include an electronic component 102 and a thermal management arrangement 104. The electronic component 102 may be thermally coupled to the thermal management arrangement 104 such that heat Q sourced from the electronic component 102 during operation is transferred to the thermal management arrangement 104.

The thermal management arrangement 104 may include a heat spreader plate 106 that includes one or more pulsating heat pipes 108 (one pulsating heat pipe shown in FIG. 1). The pulsating heat pipes 108 may have a valve 109 to allow the pulsating heat pipes 108 to be partially filled with a fluid at subatmospheric pressure. After fluid has been added, the valve 109 may be closed and sealed (either permanently or temporarily) in order to provide the pulsating heat pipes 108 with a hermetically sealed boundary to prevent leakage of the fluid in whichever phase the fluid is in (e.g., liquid, gaseous, or vapor).

The pulsating heat pipes 108 may form a circuitous, closed-loop path throughout the heat spreader plate 106. The pulsating heat pipes 108 may be fully integrated into the heat spreader plate 106 by being molded or otherwise embedded therein. Fully integrated, as used herein, means all parts of the pulsating heat pipes 108, for the entire closed-loop path, are disposed within the heat spreader plate 106.

As briefly discussed above, operation of the electronic component 102 may result in heat Q being transferred to the thermal management arrangement 104. Specifically, the heat may be initially transferred to a section 110 of the heat spreader plate 106. Section 110 may then operate as an evaporator to induce a liquid-to-vapor phase transition of fluid within portions of the pulsating heat pipes 108 located in section 110. Section 110, when operating as an evaporator, may hereinafter be referred to as an operative evaporator 110.

Vapor bubbles 112 formed by the operative evaporator 110 may flow towards a section 114 of the heat spreader plate 106, which operates as a condenser to induce a vapor-to-liquid phase transition of fluid within section 114. Section 114, when operating as a condenser, may hereinafter be referred to as an operative condenser 114.

The condensation/evaporation cycle of the fluid within the pulsating heat pipes 108 may cause a periodic or oscillating flow of the vapor bubbles 112 and liquid slugs 116 between the operative evaporator 110 and the operative condenser 114. The fluid pulsating between the operative evaporator 110 and the operative condenser 114 may transfer heat by accumulating thermal energy through evaporation in the operative evaporator 110 and depositing the accumulated thermal energy through condensation in the operative condenser 114.

The pulsating heat pipes 108, operating as described, may provide the fluid with significant heat carrying capacities. These capacities may be achieved without employing any of the wicking structures of conventional heat pipes. Hence the heat spreader plate 106 and fully integrated pulsating heat pipes 108 may not have the same dimensional limitations associated with the wicking structures and, therefore, may have a smaller thickness compared to conventional heat pipes.

In various embodiments, the heat spreader plate 106 may be comprised of a thermally conductive material such as, but not limited to, aluminum (Al), copper (Cu), annealed pyrolytic graphite (APG), etc.

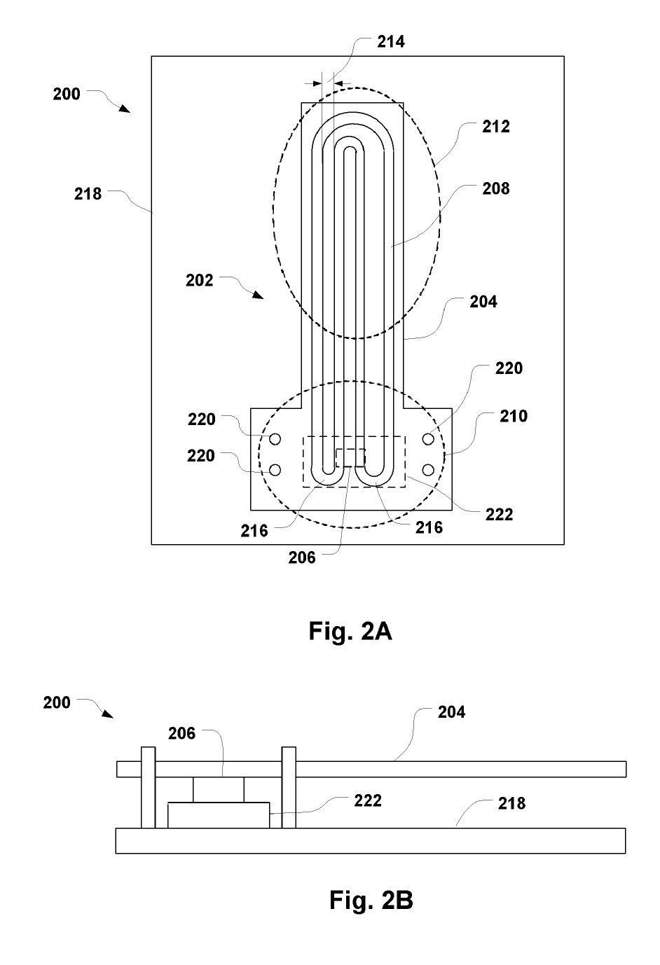

FIGS. 2A and 2B illustrate top and side cross-sectional views of a system 200 in accordance with an embodiment. The system 200 may be similar to system 100 with like-named components operating similarly and being substantially interchangeable.

The system 200 may include a thermal management arrangement 202 having a heat spreader plate 204 that is both physically and thermally coupled to an electronic component, e.g., a die of die package 206. The heat spreader plate 204 may include a pulsating heat pipe 208 fully integrated therein. The heat spreader plate 204 may transfer heat from an operative evaporator 210 to an operative condenser 212 in a manner similar to that as described above.

In some embodiments, the small dimensions of the pulsating heat pipe 208, relative to conventional wicking heat pipes, may enable effective thermal management at least in part due to a pitch 214 between adjacent pipe segments being of a magnitude that allows a plurality of pipe bends 216 to be in the vicinity of the die package 206. The small dimensions of the pulsating heat pipe 208 may also allow the heat spreader plate 204 to remain relatively thin, e.g., 1.3 millimeters (mm) to 2 mm. A heat spreader plate having a thickness within this range may be referred to as a low-profile heat spreader plate.

A low-profile heat spreader plate may reduce the cost and weight of the thermal management arrangement 202 as well as increase the overall heat carrying capacity by placing the fluid in closer proximity to the die package 206. Employing a low-profile heat spreader plate may also facilitate a reduction of the form factor of the system 200 by obviating the need to accommodate fans, or other flow generating devices, associated with forced-air convection cooling systems.

In accordance with some embodiments, the heat spreader plate 204 may be directly attached to the die package 206 to facilitate thermal conductance between the two components. Directly attached, as used herein, may refer to the heat spreader plate 204 being attached to the die package 206 without any other components being disposed therebetween. It may be noted, however, that some interposing materials, e.g., an adhesive, a paste, etc., will not negate a direct attachment.

The pulsating heat pipe 208 may not require the use of an interposing integrated heat spreader (IHS) to be secured to the circuit board 218 because the pulsating heat pipe 208 may be integrated into the heat spreader plate 204, which may be secured to the circuit board 218. On the other hand, the dimensions of conventional wicking heat pipes, 3 mm or greater, may not be integrated into a heat spreader plate, necessitating the use of an interposing integrated heat spreader (IHS) to secure the conventional wicking heat pipes to a die package.

Attachment of the heat spreader plate 204 to the die package 206 may be secured by the heat spreader plate 204 being fastened to a circuit board 218, e.g., a motherboard, by a number of fasteners 220 such as screws, bolts, clamps, etc.

The die package 206 may be coupled, both physically and electrically, to the circuit board 218 through a substrate 222.

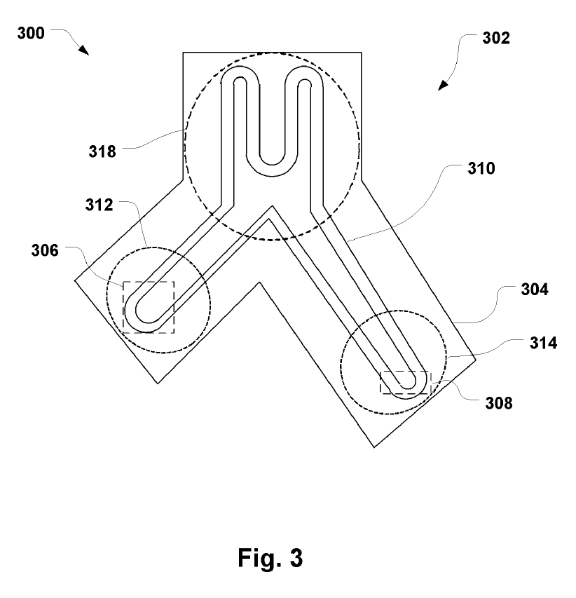

FIG. 3 is a schematic diagram of a system 300 in accordance with an embodiment. Except as otherwise noted, the system 300 may be similar to systems 100 and/or 200 with like-named components operating similarly and being substantially interchangeable.

The system 300 may include a thermal management arrangement 302 having a heat spreader plate 304 that is both physically and thermally coupled to a first electronic component 306 and to a second electronic component 308. The heat spreader plate 304 may include a pulsating heat pipe 310 fully integrated therein. The pulsating heat pipe 310 may be routed through a first extension of the heat spreader plate 304 that corresponds to the first electronic component 306 and through a second extension of the heat spreader plate 304 that corresponds to the second electronic component 308. Heat sourced from each of the electronic components may result in operative evaporators 312 and 314 transferring thermal energy to an operative condenser 318 in a manner similar to that discussed above.

In some embodiments, the first electronic component 306 may be a processing unit, e.g., a central processing unit, while the second electronic component 308 may be a controller, e.g., a memory controller, an input/output controller, etc. The heat sourced by each of the electronic components may vary. Accordingly, in some embodiments the heat transfer capacities of the various extensions may be correspondingly modified. Modifying the heat transfer capacities in each of the extensions may be done by varying the cross-sectional area of the heat pipes in the various extensions, varying the number of pipe bends, varying the number of closed loops, etc.

In various embodiments, the heat spreader plate 304 may be directly attached to the first electronic component 306 and/or the second electronic component 308. In some embodiments, one electronic component may be directly attached to the heat spreader plate 304 while one or more interposing components (e.g., an integrated heat spreader) may be disposed between the other electronic component and the heat spreader plate 304.

In some embodiments, the section of the pulsating heat pipe 310 between the first electronic component 306 and the second electronic component 308 may be located entirely in the operative evaporator 312 and/or 314 without any portion being located in the operative condenser 318. In other embodiments, and as generally shown in FIG. 3, the section of the pulsating heat pipe 310 between the first electronic component 306 and the second electronic component 308 may be at least partially located in the operative condenser 318.

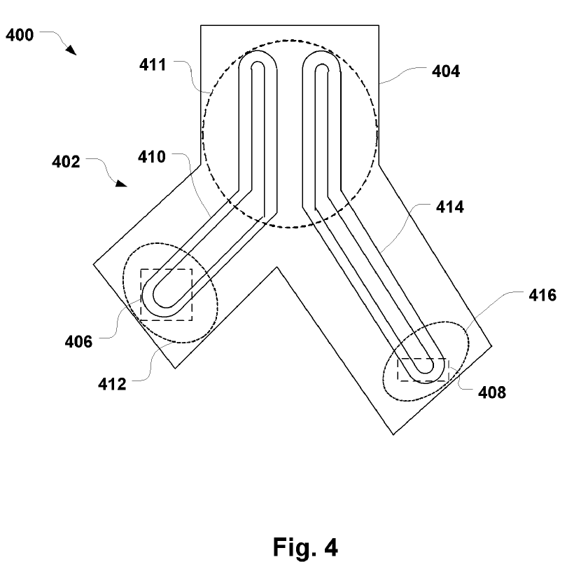

FIG. 4 is a schematic diagram of a system 400 in accordance with an embodiment. Except as otherwise noted, the system 400 may be similar to systems 100, 200, and/or 300 with like-named components operating similarly and being substantially interchangeable.

The system 400 may include a thermal management arrangement 402 having a heat spreader plate 404 that is both physically and thermally coupled to a first electronic component 406 and to a second electronic component 408, similar to the configuration of system 300. However, in this embodiment the heat spreader plate 404 may include a first pulsating heat pipe 410 that is routed between an operative condenser 411 and an operative evaporator 412 in the extension of the heat spreader plate 404 that corresponds to the first electronic component 406 and a second pulsating heat pipe 414 that is routed between the operative condenser 411 and an operative evaporator 416 in the extension of the heat spreader plate 404 that corresponds to the second electronic component 408. In other embodiments, the heat spreader plate 404 may have more than two pulsating heat pipes. While each of the pulsating heat pipes are shown with only one pipe bend in each evaporator section, other embodiments may include various number of pipe bends and/or various number of closed pipe loops based on desired heat transfer capacities.

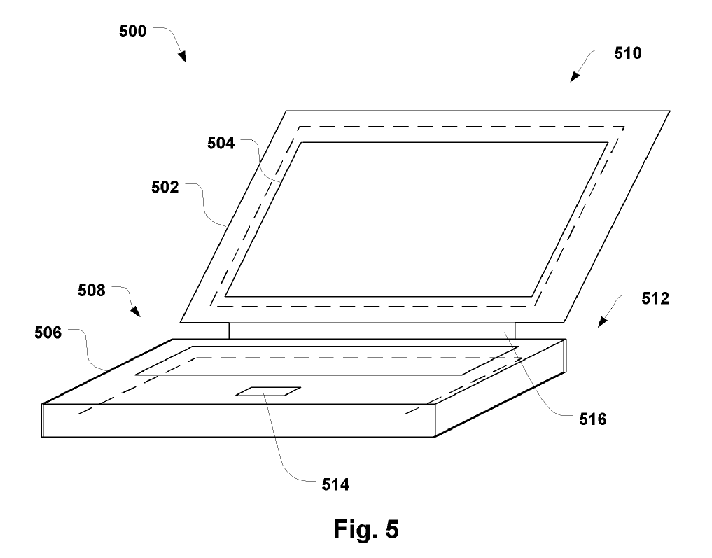

FIG. 5 illustrates a laptop computing device 500 in accordance with an embodiment. The laptop computing device 500 may have a housing including a cover 502, which houses a display 504, and a base 506, which houses one or more input devices 508 (e.g., keyboard, pointer control device, etc.) as is well known. The cover 502 may be rotatably coupled to the base 506. In this embodiment, the laptop computing device may have a thermal management arrangement 510 disposed in the cover 502 and/or thermal management arrangement 512 disposed in the base 506. The thermal management arrangements, which may be any combination of the above-described thermal management arrangements, may operate to evenly distribute heat along an adjacent surface of the laptop computing device 500 where it may be passively dissipated. The heat may be sourced from any electronic components thermally coupled to either of the thermal management arrangements. The electronic components may include the display 504, a processing unit, a controller, etc.

In some embodiments, the electronic components in the base 506 may generate a disproportionate amount of the overall heat of the laptop computing device 500. Accordingly, a thermal hinge 516 may be used to thermally, as well as rotatably, couple the base 506 to the cover 502. In this manner, excessive heat may be transferred from the electronic components in the base 506 to the thermal management arrangement 510 where it is spread and passively dissipated.

In some embodiments, the thermal management arrangements 510 and/or 512 may be low-profile thermal management arrangements in order to reduce the overall form factor of the laptop computing device 500. Furthermore, the passive heat dissipation of the thermal management arrangements 510 and/or 512 may provide for sufficient heat transfer capabilities without requiring the additional bulk, weight, and expense of implementing a forced air convection thermal management arrangement. The laptop computing device 500 may be referred to as a fanless laptop computing device in embodiments in which a forced air convection thermal management arrangement is not employed.

In some embodiments, other thermal management features may be employed in conjunction with the thermal management arrangements 510 and/or 512 to route heat as desired for a particular embodiment. These other features may include, e.g., wicking heat pipes, forced air convection arrangements, etc.

In some embodiments, techniques of the manufacture of the thermal management arrangements 510 and/or 512 may also be configured to reduce the form factor, weight, and expense of the laptop computing device 500.

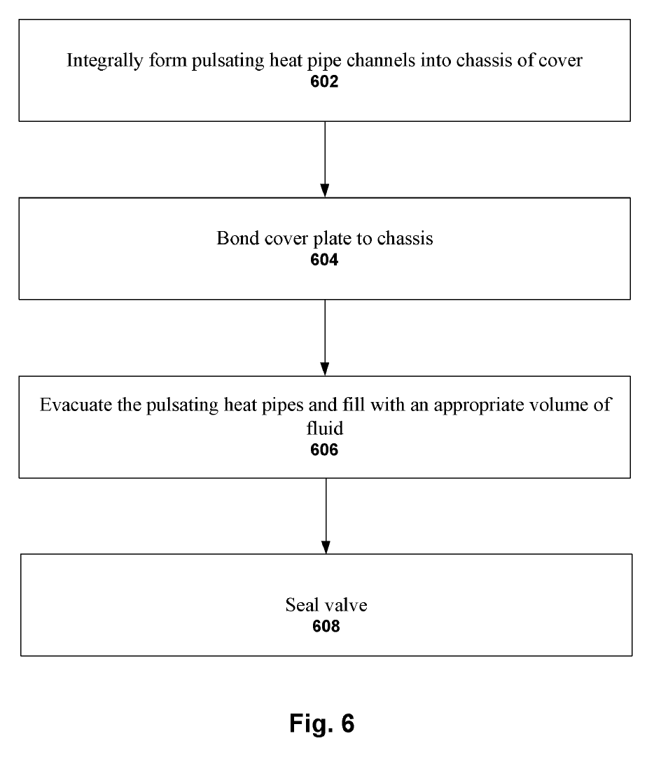

FIG. 6 is a flow diagram illustrating a manufacturing operation of the thermal management arrangement 510 in accordance with an embodiment of the present invention. At block 602, channels for one or more pulsating heat pipes may be integrally formed into a chassis of the cover 502. As used herein, integrally formed may refer to formation of the channels at the same time, and of the same material, as the chassis of the cover 502. In some embodiments, this may be done by the channel features being part of the mold of the chassis.

At block 604, a cover plate may be bonded to the chassis such that features of the cover plate and the channel features form the one or more pulsating heat pipes.

At block 606, the one or more pulsating heat pipes may be evacuated through a valve and filled with an appropriate amount of fluid. At block 608, the valve may be sealed.

After the thermal management arrangement 510 is formed, the display 504 may be face coupled to the cover plate. As used herein, face coupling may refer to the coupling of the two components at respective faces.

Forming the thermal management arrangement 510 as described may not only reduce cost, weight, and the overall form factor, it may also improve heat transfer efficiencies by the chassis of the cover 502 acting as a part of the heat spreader plate. Therefore, heat generated by the display 504 may be effectively dissipated through the cover 502.

In some embodiments, the thermal management arrangement 512 may be integrally formed into the chassis of the base 506 in a similar manner.

Although specific embodiments have been illustrated and described herein for purposes of description of various embodiments, it will be appreciated by those of ordinary skill in the art that a wide variety of alternate and/or equivalent implementations calculated to achieve the same purposes may be substituted for the specific embodiments shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A system comprising:
a processing unit;
a display communicatively coupled to the processing unit; and
a heat spreader plate thermally coupled to the display and/or the processing unit, the heat spreader plate having one or more pulsating heat pipes with each of the one or more pulsating heat pipes configured to contain a fluid within a sealed boundary, the heat spreader plate having a first section to operate as an evaporator in a presence of heat sourced from the display and/or the processing unit to induce a liquid-to-vapor phase change of fluid within a portion of the one or more pulsating heat pipes in the evaporator, and a second section to operate as a condenser to induce a vapor-to-liquid phase change of fluid within a portion of the one or more pulsating heat pipes in the condenser such that the fluid pulsates between the evaporator and the condenser to transfer heat sourced from the display and/or the processing unit to the condenser.

2. The system of claim 1, wherein the processing unit includes a die package and the heat spreader plate is directly attached to the die package.

3. The system of claim 2, further comprising:
a circuit board fastened to the heat spreader plate in a manner to secure direct attachment of the heat spreader plate to the die package.

4. The system of claim 1, wherein the system is a laptop computing device.

5. The system of claim 4, wherein the laptop computing device is a fanless laptop computing device.

6. The system of claim 1, further comprising:
a housing to house the display, the processing unit, and the heat spreader plate.

7. The system of claim 6, wherein the housing includes a cover to house the display and a base to house the processing unit.

8. The system of claim 7, wherein the cover is to further house the heat spreader plate.

9. The system of claim 8, further comprising:
a thermal hinge rotatably and thermally coupling the cover to the base.

10. The system of claim 1, wherein the heat spreader plate has a thickness of approximately two millimeters or less.

11. An apparatus comprising:
one or more pulsating heat pipes, each of the one or more pulsating heat pipes configured to contain a fluid within a sealed boundary; and
a heat spreader plate having the one or more pulsating heat pipes integrated therein, the heat spreader plate configured to be disposed within a housing of a computing device and having a first section and a second section configured to operate as evaporators, when thermally coupled to respective first and second operating electronic components, to induce a liquid-to-vapor phase change of fluid within a portion of the one or more pulsating heat pipes in the evaporators, and a third section configured to operate as a condenser to induce a vapor-to-liquid phase change of fluid within one or more portions of the one or more pulsating heat pipes in the condenser such that the fluid pulsates between the evaporators and the condenser to transfer heat sourced from the first and second operating electronic components to the condenser.

12. The apparatus of claim 11, wherein the first operating electronic component is a processing unit and the second operating electronic component is a controller.

13. The apparatus of claim 11, wherein the one or more pulsating heat pipes include a pulsating heat pipe routed through the first section, the second section, and the third section.

14. The apparatus of claim 11, wherein the one or more pulsating heat pipes include:
a first pulsating heat pipe routed through the first section and the third section; and
a second pulsating heat pipe routed through the second section and the third section.

15. The apparatus of claim 14, wherein a cross-sectional area of the first pulsating heat pipe is different from a cross-sectional area of the second pulsating heat pipe.

16. The apparatus of claim 11, wherein the one or more pulsating heat pipes comprise one or more wickless heat pipes.

17. The apparatus of claim 11, wherein the one or more pulsating heat pipes are fully integrated into the heat spreader plate.

18. A method comprising:
forming one or more pulsating heat pipe channels integrally into a chassis of a mobile computing device;
bonding a cover plate to the chassis to form one or more pulsating heat pipes respectively corresponding to the one or more pulsating heat pipe channels;
evacuating the one or more pulsating heat pipes; and
partially filling the one or more pulsating heat pipes with a fluid.

19. The method of claim 18, wherein said evacuating and partially filling is conducted through a valve and the method further comprises:
sealing the valve after said partially filling.

20. The method of claim 18, wherein the chassis is a cover chassis of a laptop computing device and the method further comprises:
face coupling a display to the cover plate.
